(19) United States
(12) Patent Application Publication
(10) Pub. No.: US 2008/0087999 A1
(43) Pub. Date: Apr. 17, 2008

(54) Micro BGA package having multi-chip stack

(75) Inventor: Ronald Takao Iwata, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/581,085

(22) Filed: Oct. 16, 2006

(51) Int. Cl. H01L 23/00

(52) U.S. Cl. 257/686; 257/E23.001

(57) ABSTRACT

A micro BGA package comprises a first chip, a second chip, a single-layer PCB, a plurality of bonding wires, an encapsulant and a plurality of solder balls. The second chip is smaller than the first chip in size and stacked on the active surface of the first surface by facing the same direction with the first chip without covering the bonding pads of the first chip. The single-layer PCB is disposed on the second chip and smaller than the second chip in size. The single-layer PCB has a single-layer wiring pattern including a plurality of wire-connecting pads and a plurality of ball pads. By wire-bonding method, the first and second chips are electrically connected to the wire-connecting pads. The encapsulant is formed around the first chip, the second chip and the single-layer PCB to seal the bonding wires but exposes the rear surface of the first chip and the solder balls. The solder balls are disposed on the ball pads. Accordingly, the micro BGA package may reduce package size of multi-chip stack and improve thermal dissipation without increasing package thickness.

### FIELD OF THE INVENTION

The present invention relates generally to multi-chip package, and more particularly to micro BGA package having multi-chip stack that may further reduce package footprint.

### BACKGROUND OF THE INVENTION

In conventional multi-chip package design, several chips are respectively attached to a same substrate side by side, resulting in a large package footprint, so an idea to stack the chips vertically might be useful for obtaining smaller package size. Referring now to FIG. 1, therein is shown a cross-sectional view of a conventional BGA package having multi-chip stack. The package 100 comprises a first chip 110, a second chip 120, a substrate 130, a plurality of first bonding wires 141, a plurality of second bonding wires 142, an encapsulant 150 and a plurality of solder balls 160. The substrate 130 acting as a multi-chip carrier has multi-layer wiring patterns and PTH's (Plated Through Holes) (not shown in the drawings) that enables double-sided conductivity of the substrate 130 thereby electrically conducting the contact pads 133 on the upper surface 131 and the ball pads 134 on the lower surface 132. The first chip 110 is disposed on the substrate 130, and then the second chip 120 facing upwardly same direction with the first chip 110 is stacked on the active surface 111 of the first chip 110 by means of a die attach material (DAM) 170. The second chip 120 is substantially smaller than the first chip 110 and uncovers the bonding pads 112 of the first chip 110, hence the bonding pads 112 of the first chip 110 can be electrically connected to the contact pads 133 of the substrate 130 by a plurality of first bonding wires 141, and also the bonding pads 112 of the second chip 120 are electrically connected to the contact pads 133 of the substrate 130 by a plurality of second bonding wires 142. The encapsulant 150 is formed on the upper surface 131 of the substrate 130 to seal the first chip 110, the second chip 120, the first bonding wires 141 and the second bonding wires 142. The solder balls 160 are disposed on the ball pads 134 of the substrate 130. The encapsulant 150 has a thickness above the active surface 121 of the second chip 120 to prevent the second bonding wires 142 from exposure, however, thermal resistance will substantially increase. The substrate 130 is much greater than the first chip 110 so the contact pads 133 on the upper surface 131 of the substrate 130 can be arranged outside the first chip 110 for wire-bonding. Also, the substrate 130 must be multi-layer PCB (Printed Circuit Board) having plated through holes to achieve double-sided electrical conductivity that results in a high cost for substrate fabrication. Accordingly it is necessary to further improve some problems such as reducing package footprint, decreasing thermal resistance and lowering substrate-fabricating cost for the conventional BGA package 100 having multi-chip stack.

### SUMMARY

In order to solve the problems mentioned above, the primary object of the present invention is to provide a micro BGA package having multi-chip stack, which enables multiple chip that is stacked in different size or crisscross stacked in same size to be integrated into a micro BGA package to obtain some efficiencies such as reducing package footprint by multi-chip stack, enhancing thermal dissipation, concentrating solder balls and lowering substrate-fabricating cost.

The secondary object of the present invention is to provide a micro BGA package having multi-chip stack, which may substantially decrease thermal resistance of the encapsulant and shorten electrical connection path.

The third object of the present invention is to provide a micro BGA package having multi-chip stack, which allows multiple chip to be stacked more effectively to reduce package footprint and enhance thermal dissipation without increasing overall package thickness.

One aspect of the present invention provides a micro BGA package having multi-chip stack, which mainly comprises a first chip, a second chip, a single-layer PCB, a plurality of first bonding wires, a plurality of second bonding wires, an encapsulant and a plurality of solder balls. A plurality of first bonding pads is disposed about the periphery of the active surface of the first chip and a plurality of second bonding pads is disposed about the periphery of the active surface of the second chip. The second chip is smaller than the first chip and stacked on the first chip, hence the second chip does not cover the first bonding pads. The single-layer PCB is disposed on the second chip but smaller than the second chip in size, and has a single-layer wiring pattern including a plurality of wire-connecting pads and a plurality of ball pads. The first bonding wires are applied to electrically connect the first bonding pads to the wire-connecting pads and the second bonding wires are applied to connect the second bonding pads to the wire-connecting pads. The encapsulant is formed around the first chip, the second chip and the single-layer PCB to seal the first and second bonding wires, but exposes the ball pads and the rear surface of the first chip. The solder balls are disposed on the ball pads of the single-layer PCB.

With respect to the micro BGA package mentioned above, the second chip may have a size smaller than that of the first chip to expose the first bonding pads for encapsulation and wire-bonding.

With respect to the micro BGA package mentioned above, both the first chip and the second chip may be flash memory and the memory capacity of the second chip is smaller than that of the first chip.

With respect to the micro BGA package mentioned above, the second chip may have a same size with the first chip and be crisscross stacked on the first chip to expose the first bonding pads prior to encapsulation.

With respect to the micro BGA package mentioned above, both the first chip and the second chip may be flash memory and the memory capacity of the second chip may be the same as that of the first chip.

With respect to the micro BGA package mentioned above, the encapsulant may cover the first bonding wires, the second bonding wires, the wire-connecting pads and the sides of the first chip.

With respect to the micro BGA package mentioned above, the single-layer PCB is lack of plated through hole (PTH).

With respect to the micro BGA package mentioned above, it further comprises a thermal spreader attached to the rear surface of the first chip and a coplanar surface of the encapsulant.

With respect to the micro BGA package mentioned above, the thermal spreader may have a plurality of thermal fins.

With respect to the micro BGA package mentioned above, the single-layer PCB may be a flexible PCB and attached to the active surface of the second chip by means of a buffer resin.

### DESCRIPTION OF THE DRAWINGS

FIG. 1 is a cross-sectional view illustrating a conventional micro BGA package having multi-chip stack.

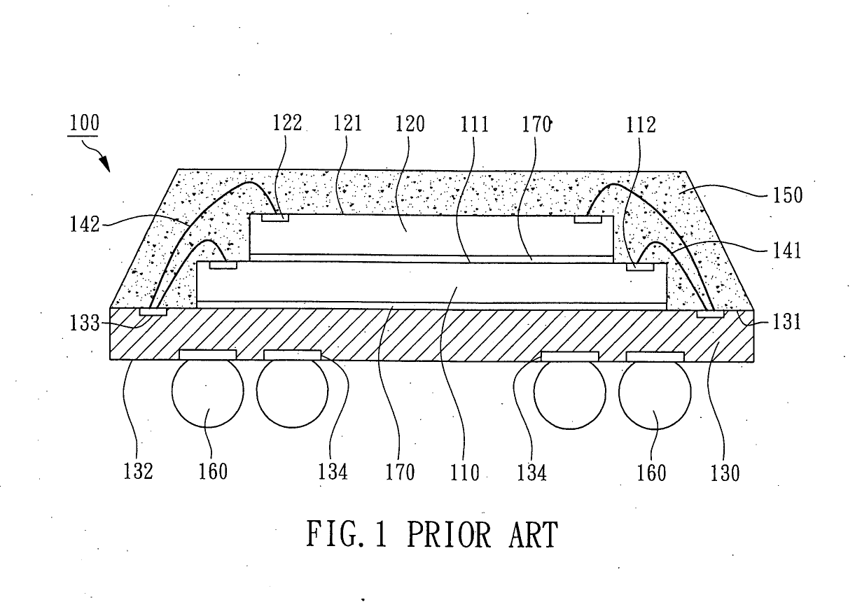

FIG. 2 is a cross-sectional view illustrating a micro BGA package having multi-chip stack in accordance with the first embodiment of the present invention.

FIG. 3 is a plan view illustrating the micro BGA package prior to encapsulation in accordance with the first embodiment of the present invention.

FIG. 4 is a cross-sectional view illustrating another micro BGA package having multi-chip stack in accordance with the second embodiment of the present invention.

FIG. 5 is a plan view illustrating the micro BGA package prior to encapsulation in accordance with the second embodiment of the present invention.

FIG. 6 is a perspective view illustrating the micro BGA package prior to encapsulation in accordance with the second embodiment of the present invention.

### DETAILED DESCRIPTION OF THE PRESENT INVENTION

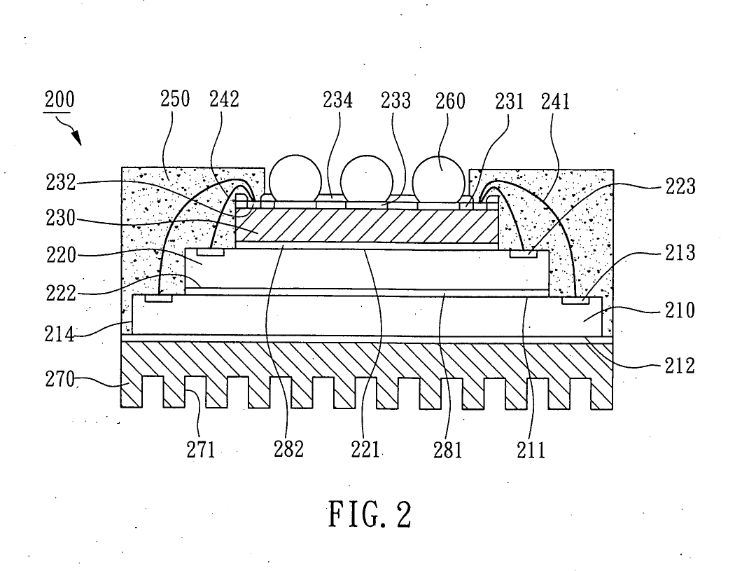

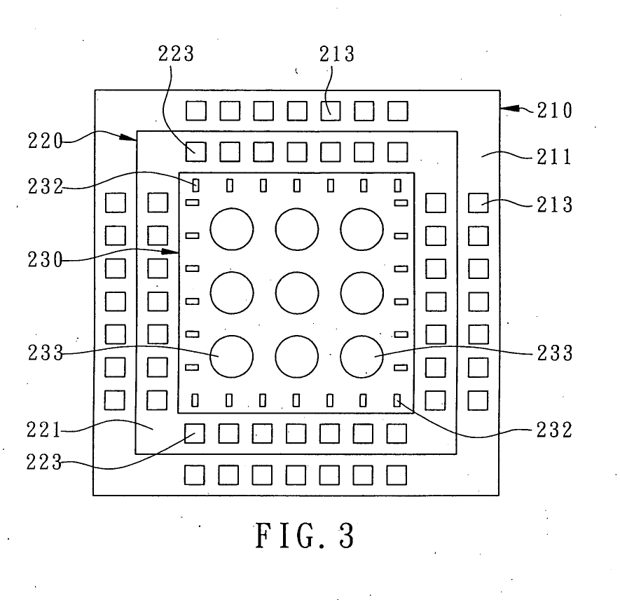

FIG. 2 shows a cross-sectional view of a micro BGA package having multi-chip stack and FIG. 3 shows a plan view of the micro BGA package having multi-chip stack according to the first embodiment of the present invention.

Referring to FIG. 2 and FIG. 3, the micro BGA package 200 typically comprises a first chip 210, a second chip 220, a single-layer PCB 230, a plurality of first bonding wires 241, a plurality of second bonding wires 242, an encapsulant 250 and a plurality of solder balls 260.

Referring now to FIG. 2, the first chip 210 has a first active surface 211 and a rear surface 212 opposing to the first active surface 211, further has a plurality of first bonding pads 213 disposed about the periphery of the first active surface 211. However, there is no need to use the multi-layer PCB of conventional BGA as a chip carrier, an adhesive tape or thermal spreader is adapted to carry chip during fabricating processes.

The second chip 220 also has a second active surface 221 and an opposing rear surface 222. A plurality of second bonding pads 223 is disposed about the periphery of the second active surface 221 of the second chip 220. The second chip 220 faces up in the same direction with the first chip 210, which is attached to and stacked on the first active surface 211 of the first chip 210 by an adhesive layer 281. Moreover, the second chip 220 is smaller than the first chip 210 so that the first bonding pads 213 are uncovered by the second chip 220. Compared with the first chip 210, the second chip 220 has a smaller size to expose the first bonding pads 213 prior to encapsulation as shown in FIG. 3. In this embodiment, both the first and second chips 210, 220 can be flash memory, such as NAND flash or NOR flash. Furthermore in this embodiment, the memory capacity of the second chip 220 is smaller than that of the first chip 210, for example the first chip 210 may have 2 G memory capacity and the second chip 220 may have 1 G only memory capacity.

The single-layer PCB 230 is disposed on the second active surface 221 of the second chip 220 and smaller than the second chip 220. Referring now to FIG. 3, the second bonding pads 223 located on the second chip 220 are uncovered by the single-layer PCB 230 and the single-layer PCB 230 is attached to the second active surface 221 of the second chip 220 by applying an adhesive layer 282. The single-layer PCB 230 has single-layer wiring pattern 231 that further includes a plurality of wire-connecting pads 232 and a plurality of ball pads 233. In this embodiment, the single-layer PCB 230 is lack of PTH (Plated Through Hole) thereby lowering substrate-fabricating cost.

Besides applying wire-bonding technique, the first bonding wires 241 are used to electrically connect the first bonding pads 213 on the first chip 210 to the corresponding wire-connecting pads 232 on the single-layer PCB 230, and the second bonding wires 242 are also used to electrically connect the second bonding pads 223 on the second chip 220 to the corresponding wire-connecting pads 232 on the single-layer PCB 230.

The encapsulant 250 is formed around the first chip 210, the second chip 220 and the single-layer PCB 230 to seal the first bonding wires 241 and the second bonding wires 242 but expose the ball pads 233 and the rear surface 212 of the first chip 210. A transfer molding technique can be utilized to form the encapsulant 250. Referring now to FIG. 2, the encapsulant 250 substantially covers the first bonding wires 213, the second bonding wires 223, the wire-connecting pads 232 and the sides 214 of the first chip 210. The solder balls 260 are disposed on the ball pads 233 of the single-layer PCB 230.

The micro BGA package 200 desirably may further include a thermal spreader 270 that is attached to the rear surface 212 of the first chip 210 and the coplanar surface of the encapsulant 250 to improve thermal dissipation. Besides, the thermal spreader 270 may further have a plurality of thermal fins 271 to enhance thermal dissipation more effectively.

Therefore the micro BGA package 200 integrates multiple chips 210 and 220 into a BGA package, minimizes package footprint of multi-chip stack without increasing package thickness, solves thermal resistance problem of the encapsulant 250, enables the solder balls 260 to be concentrated, as well as saves substrate-fabricating cost. Particularly, if a flexible PCB having a thinner thickness is used as the single-layer PCB 230, there is an extra space to form an adhesive layer 282 with a thicker buffer resin to protect the solder balls 260 located at the substrate corners from directly taking thermal stress.

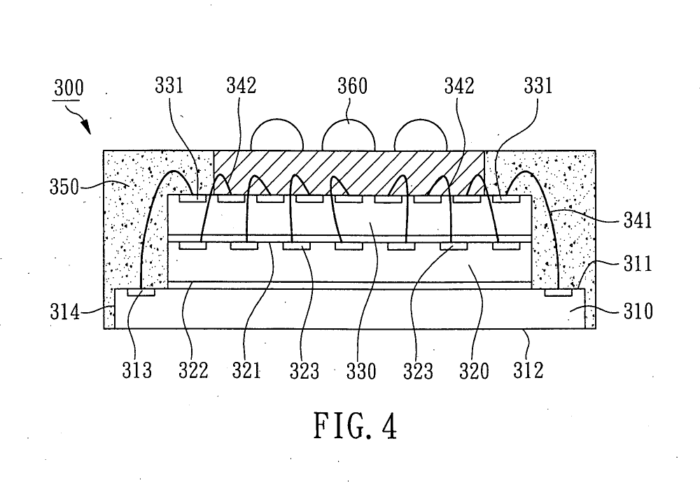

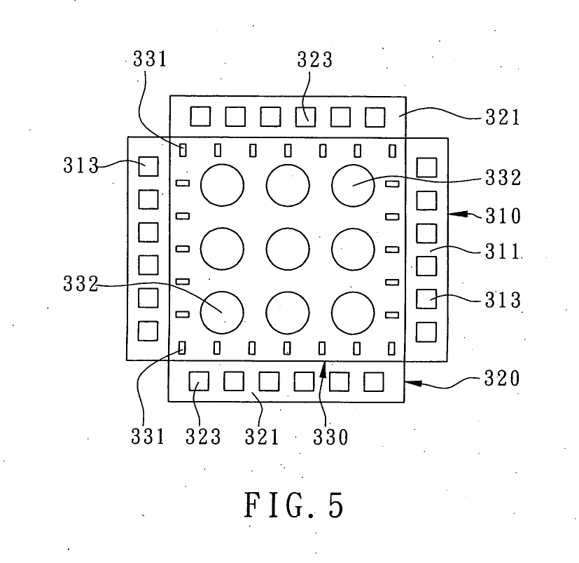

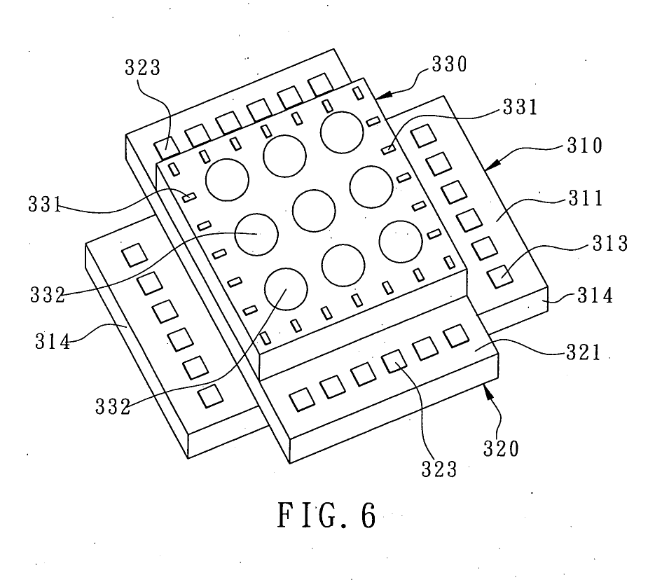

According to the second embodiment of the present invention, FIG. 4 shows a cross-sectional view of another micro BGA package, FIG. 5 shows a plan view of the micro BGA package prior to encapsulation, and FIG. 6 shows a perspective view of the micro BGA package prior to encapsulation.

Referring now to FIG. 4, a micro BGA package 300 typically comprises a first chip 310, a second chip 320, a single-layer PCB 330, a plurality of first bonding wires 341, a plurality of second bonding wires 342, an encapsulant 350 and a plurality of solder balls 360. A plurality of first bonding pads 313 is disposed about the periphery of a first active surface 311 of the first chip 310 and a plurality of second bonding pads 323 is disposed about the periphery of a second active surface 321 of the second chip 320. The second chip 320 is disposed on the first active surface 311 of the first chip 310. Referring now to FIG. 5 and FIG. 6, in this embodiment, the second chip 320 has a same size with the first chip 310 and is crisscross stacked on the first chip 310 to expose the first bonding pads 313 prior to encapsulation. Both the first and the second chips 310, 320 can be flash memory and have same memory capacity. The single-layer PCB 330 only has a wiring pattern (not showed in the drawings) including a plurality of wire-connecting pads 331 and a plurality of ball pads 332, which is disposed on the second chip 320 and smaller than the second chip 320. The first bonding wires 341 are applied to electrically connect the first bonding pads 313 to the wire-connecting pads 331, and also the second bonding wires 342 are applied to electrically connect the second bonding pads 323 to the wire-connecting pads 331. The encapsulant 350 is formed around the first chip 310, the second chip 320 and the single-layer PCB 330 to seal the first bonding wires 341 and the second bonding wires 342 but expose the rear surface 312 of the first chip 310. The encapsulant 350 substantially covers the first bonding pads 313, the second bonding pads 323, the wire-connecting pads 331 and the sides 314 of the first chip 310. The solder balls 360 are disposed on the ball pads 332 located on the single-layer PCB 330.

Accordingly, multiple chip 310, 320 having same size can be stacked and packaged into the micro BGA package 300, which has some merits such as reducing package size, eliminating thermal resistance of encapsulation, concentrating solder balls and saving substrate-fabricating cost.

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A micro BGA package having multi-chip stack, comprising:
a first chip having a first active surface and a plurality of first bonding pads disposed about the periphery of the first active surface;
at least a second chip a second active surface and a plurality of second bonding pads disposed about the periphery of the second active surface, the second chip smaller than the first chip in size and stacked on the first active surface of the first chip not to cover the first bonding pads;
a single-layer PCB disposed on the second active surface of the second chip and smaller than the second chip, the single-layer PCB having a single-layer wiring pattern including a plurality of wire-connecting pads and a plurality of ball pads;
a plurality of first bonding wires electrically connecting the first bonding pads to the wire-connecting pads;
a plurality of second bonding wires electrically connecting the second bonding pads to the wire-connecting pads;
an encapsulant formed around the first chip, the second chip and the single-layer PCB to seal the first bonding wires and the second bonding wires but expose the ball pads and a rear surface of the first chip opposing to the first active surface; and
a plurality of solder balls disposed on the ball pads.

2. The micro BGA package in accordance with claim 1, wherein the second chip has a size smaller than that of the first chip to uncover the first bonding pads for encapsulation and wire-bonding.

3. The micro BGA package in accordance with claim 2, wherein both the first and second chips are flash memory but the memory capacity of the second chip is smaller than that of the first chip.

4. The micro BGA package in accordance with claim 1, wherein the second chip has a same size with the first chip and is crisscross stacked on the first chip without covering the first bonding pads.

5. The micro BGA package in accordance with claim 4, wherein both the first and second chips are flash memory and have the same memory capacity

6. The micro BGA package in accordance with claim 1, wherein the encapsulant covers the first bonding pads, the second bonding pads, the wire-connecting pads and the sides of the first chip.

7. The micro BGA package in accordance with claim 1, wherein the single-layer PCB is lack of plated through hole (PTH).

8. The micro BGA package in accordance with claim 1, further comprising a thermal spreader attached to the rear surface of the first chip and a coplanar surface of the encapsulant.

9. The micro BGA package in accordance with claim 8, wherein the thermal spreader has a plurality of thermal fins.

10. The micro BGA package in accordance with claim 1, wherein the single-layer PCB is a flexible PCB attached to the second active surface of the second chip by applying a buffer resin.
